(19) United States
(12) Patent Application Publication
(10) Pub. No.: US 2024/0429197 A1
(43) Pub. Date: Dec. 26, 2024

(54) SEMICONDUCTOR PACKAGE AND METHOD OF MANUFACTURING THE SAME

(71) Applicant: SAMSUNG-RO, ELECTRONICS CO., LTD, Suwon-si (KR)

(72) Inventors: Jing Cheng LIN, Suwon-si (KR); Youngkun JEE, Suwon-si (KR)

(73) Assignee: SAMSUNG-RO, ELECTRONICS CO., LTD, Suwon-si (KR)

(21) Appl. No.: 18/753,756

(22) Filed: Jun. 25, 2024

(30) Foreign Application Priority Data
Jun. 26, 2023 (KR) 10-2023-0082129

(51) Int. Cl. H01L 23/00; H01L 21/304; H01L 21/56; H01L 23/29; H01L 23/538; H01L 25/18

(52) U.S. Cl. CPC H01L 24/81; H01L 21/304; H01L 21/568; H01L 23/5386; H01L 24/13; H01L 23/29; H01L 25/18; H01L 2224/13147; H01L 2224/81143; H01L 2224/81193; H01L 2224/81815; H01L 2224/81895; H01L 2924/3511

(57) ABSTRACT

A method of manufacturing a semiconductor package according to embodiments of the present disclosure has an effect of reducing the size of the semiconductor package by minimizing a distance between semiconductor chips by self-aligning the semiconductor chips on pads having fine gaps due to the surface tension of solder bumps.

### CROSS-REFERENCE TO RELATED APPLICATION

This application is based on and claims priority under 35 U.S.C. § 119 to Korean Patent Application No. 10-2023-0082129, filed on Jun. 26, 2023, in the Korean Intellectual Property Office, the disclosure of which is incorporated by reference herein in its entirety.

### BACKGROUND

Embodiments are related to a semiconductor package and a method of manufacturing the same, and more particularly, to a method of manufacturing a semiconductor package including a bridge die.

Recently, due to the significant progress in the electronics industry and the demand of users, electronic devices are becoming more compact and multi-functional and have greater capacity, thus requiring a highly integrated semiconductor chip. Therefore, a semiconductor package is being designed that includes a highly integrated semiconductor chip with an increased number of connection terminals for input/output (I/O) and simultaneously has ensured connection reliability. For example, a semiconductor package including a bridge die between connection terminals is being developed.

### SUMMARY

Embodiments provide a method of manufacturing a semiconductor package, by which the size of the semiconductor package may be reduced by minimizing a distance between semiconductor chips by self-aligning the semiconductor chips on pads having fine gaps due to the surface tension of solder bumps.

Embodiments are not limited to problems mentioned above, and other problems not mentioned above will be clearly understood by those skilled in the art from the following description.

Provided herein is a method of manufacturing a semiconductor package, the method including: forming, on a first carrier substrate, a plurality of sacrificial pads each having a first width; arranging, on the plurality of sacrificial pads, first semiconductor chips and second semiconductor chips disposed to be parallel to the first semiconductor chips, each of the first and the second semiconductor chips including a plurality of first metal pillars each having the first width and a plurality of sacrificial solder bumps disposed below the plurality of first metal pillars; bonding the plurality of sacrificial solder bumps to the plurality of sacrificial pads corresponding thereto between the first and the second semiconductor chips and the first carrier substrate; forming a first molding layer to at least partially surround the plurality of sacrificial pads, the plurality of sacrificial solder bumps, the plurality of first metal pillars, and the first and second semiconductor chips; attaching a second carrier substrate onto upper surfaces of the first semiconductor chips and upper surfaces of the second semiconductor chips and removing the first carrier substrate; first grinding and removing all of the plurality of sacrificial pads and the plurality of sacrificial solder bumps to at least partially expose the plurality of first metal pillars; forming a plurality of metal posts on some of the plurality of first metal pillars; bonding a plurality of connection bumps to others of the plurality of first metal pillars corresponding thereto such that a bridge die including a plurality of second metal pillars and the plurality of connection bumps disposed below the plurality of second metal pillars overlaps a portion of each of the first and second semiconductor chips in a vertical direction; forming an underfill between the bridge die and the first molding layer to at least partially surround the plurality of second metal pillars and the plurality of connection bumps; forming a second molding layer to at least partially surround the plurality of metal posts, the underfill, and the bridge die; second grinding and removing a first upper portion of the bridge die and a second upper portion of the second molding layer to at least partially expose the plurality of metal posts; forming a redistribution layer on the second molding layer, the plurality of metal posts, and the bridge die; forming an external connection terminal on the redistribution layer; and removing the second carrier substrate.

Also provided herein is a method of manufacturing a semiconductor package, the method including: forming, on a first carrier substrate, a plurality of sacrificial pads; arranging, on the plurality of sacrificial pads, a plurality of semiconductor chips disposed to be parallel to each other, each of the plurality of semiconductor chips including a plurality of first metal pillars and a plurality of sacrificial solder bumps disposed below the plurality of first metal pillars; bonding the plurality of sacrificial solder bumps to the plurality of sacrificial pads corresponding thereto between the plurality of semiconductor chips and the first carrier substrate, wherein the plurality of first metal pillars and the plurality of sacrificial pads are self-aligned with each other due to surface tension of the plurality of sacrificial solder bumps; forming a first molding layer to at least partially surround the plurality of sacrificial pads, the plurality of sacrificial solder bumps, the plurality of first metal pillars, and the plurality of semiconductor chips; attaching a second carrier substrate onto upper surfaces of the plurality of semiconductor chips and removing the first carrier substrate; first grinding and removing all of the plurality of sacrificial pads and the plurality of sacrificial solder bumps to at least partially expose the plurality of first metal pillars; forming a plurality of metal posts on some of the plurality of first metal pillars; bonding a plurality of connection bumps to others of the plurality of first metal pillars corresponding thereto such that at least one bridge die including a plurality of second metal pillars and the plurality of connection bumps disposed below the plurality of second metal pillars overlaps portions of at least two of the plurality of semiconductor chips in a vertical direction; forming at least one underfill between each of the at least one bridge die and the first molding layer to at least partially surround the plurality of second metal pillars and the plurality of connection bumps; forming a second molding layer, wherein the second molding layer is configured to at least partially surround the plurality of metal posts, the at least one underfill, and the at least one bridge die; second grinding and removing an upper portion of the at least one bridge die and an upper portion of the second molding layer to at least partially expose the plurality of metal posts; and forming a redistribution layer on the second molding layer, the plurality of metal posts, and the at least one bridge die.

Additionally, provided herein is a method of manufacturing a semiconductor package, the method including: forming, on a first carrier substrate, a plurality of sacrificial pads each having a first width; arranging, on the plurality of sacrificial pads, first semiconductor chips and second semiconductor chips disposed to be parallel to the first semiconductor chips, each of the first and the second semiconductor chips including a plurality of first metal pillars each having the first width and a plurality of sacrificial solder bumps disposed below the plurality of first metal pillars; bonding the plurality of sacrificial solder bumps to the plurality of sacrificial pads corresponding thereto between the first and the second semiconductor chips and the first carrier substrate; forming a first molding layer to at least partially surround the plurality of sacrificial pads, the plurality of sacrificial solder bumps, the plurality of first metal pillars, and the first and second semiconductor chips; attaching a second carrier substrate onto upper surfaces of the first semiconductor chips and upper surfaces of the second semiconductor chips and removing the first carrier substrate; first grinding and removing all of the plurality of sacrificial pads and the plurality of sacrificial solder bumps to at least partially expose the plurality of first metal pillars; forming a plurality of metal posts on some of the plurality of first metal pillars; bonding a plurality of connection bumps to others of the plurality of first metal pillars corresponding thereto such that a bridge die including a plurality of second metal pillars and the plurality of connection bumps disposed below the plurality of second metal pillars overlaps a portion of each of the first and the second semiconductor chips in a vertical direction; forming an underfill between the bridge die and the first molding layer to at least partially surround the plurality of second metal pillars and the plurality of connection bumps; forming a second molding layer to at least partially surround the plurality of metal posts, the underfill, and the bridge die; second grinding and removing an upper portion of the bridge die and an upper portion of the second molding layer to at least partially expose the plurality of metal posts; forming a first redistribution layer on the second molding layer, the plurality of metal posts, and the bridge die; attaching a third carrier substrate onto the first redistribution layer and removing the second carrier substrate; forming a plurality of connection posts arranged around the first and the second semiconductor chips and electrically connected with the first redistribution layer through the first molding layer and the second molding layer; forming a second redistribution layer on the first molding layer, the plurality of connection posts, and the first and the second semiconductor chips; arranging a third semiconductor chip on the second redistribution layer; and removing the third carrier substrate.

### BRIEF DESCRIPTION OF THE DRAWINGS

Embodiments will be more clearly understood from the following detailed description taken in conjunction with the accompanying drawings in which:

FIG. 1 is a plan view of main components of a semiconductor package according to an embodiment;

FIG. 2 is a cross-sectional view of the semiconductor package of FIG. 1 taken along line CX1-CX1′ of FIG. 1;

FIGS. 3 to 6 are views illustrating various embodiments;

FIG. 7 is a flowchart illustrating a method of manufacturing a semiconductor package, according to an embodiment;

FIGS. 8 to 21 are views illustrating, in a process order, a method of manufacturing a semiconductor package, according to an embodiment;

FIG. 22 is a flowchart illustrating a method of manufacturing a semiconductor package, according to another embodiment; and

FIGS. 23 to 28 are views illustrating, in a process order, a method of manufacturing a semiconductor package, according to another embodiment.

### DETAILED DESCRIPTION OF THE EMBODIMENTS

Hereinafter, embodiments will be described in detail with reference to the accompanying drawings.

Throughout the specification, an upper surface/above/on and a lower surface/under/below may be applied differently depending on the direction shown in each drawing. For example, an upper surface/above/on in one drawing (a drawing with a vertical arrow pointing upward) may be referred to as a lower surface/under/below in another drawing (a drawing with a vertical arrow pointing downward).

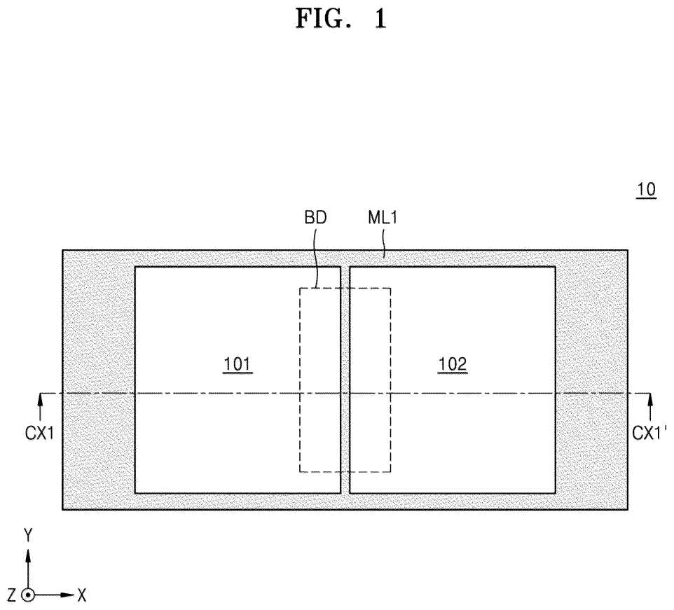

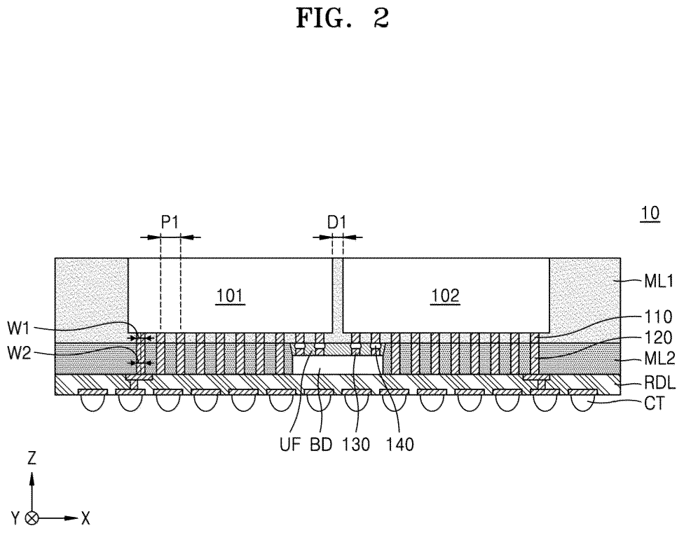

FIG. 1 is a plan view of main components of a semiconductor package according to an embodiment, and FIG. 2 is a cross-sectional view of the semiconductor package of FIG. 1 taken along line CX1-CX1′ of FIG. 1.

Referring to FIGS. 1 and 2, a semiconductor package 10 is shown that includes first and second semiconductor chips 101 and 102 arranged apart from each other in a first horizontal direction X and a bridge die BD arranged to overlap the first and second semiconductor chips 101 and 102 in a vertical direction Z.

Each of the first and second semiconductor chips 101 and 102 is a memory chip, and for example, may include a volatile memory chip and/or a non-volatile memory chip. In some embodiments, the first and second semiconductor chips 101 and 102 may be configured as a set of memory chips capable of merging data with each other.

Each of the first and second semiconductor chips 101 and 102 may include a semiconductor substrate having upper and lower surfaces facing each other, and a plurality of first metal pillars 110 formed on a lower surface of the semiconductor substrate. Some of the plurality of first metal pillars 110 may be connected to a redistribution layer RDL via a plurality of metal posts 120. In addition, the remaining ones of the plurality of first metal pillars 110 may be connected to the bridge die BD via a plurality of second metal pillars 130 and a plurality of connection bumps 140.

In a system in package in which a plurality of individual semiconductor chips are integrated into one package, the number of memory chips of the semiconductor package 10 may vary depending on applications of the semiconductor package 10. In other words, the number of memory chips of the semiconductor package 10 is not limited to the number thereof shown in the drawings.

The bridge die BD may include a base substrate and the plurality of second metal pillars 130 formed on an upper surface of the base substrate. The base substrate may be a wafer including silicon (Si), for example, crystalline silicon, polycrystalline silicon, or amorphous silicon. The plurality of second metal pillars 130 may be electrically connected with the first and second semiconductor chips 101 and 102 via the plurality of connection bumps 140 formed on upper surfaces of the plurality of second metal pillars 130.

In some embodiments, the bridge die BD may further include a circuit region (not shown), and a buffer circuit capable of controlling capacitance loading of the first and second semiconductor chips 101 and 102 may be formed in the circuit region. In some embodiments, the circuit region may include at least one selected from a transistor, a diode, a capacitor, and a resistor. In some embodiments, the bridge die BD may be an interposer.

In addition, the bridge die BD may be disposed below a region between the first and second semiconductor chips 101 and 102 to overlap each of the first and second semiconductor chips 101 and 102 in the vertical direction Z. In other words, in a plan view, a portion of the bridge die BD may be arranged to overlap the first semiconductor chip 101, and another portion of the bridge die BD may be arranged to overlap the second semiconductor chip 102.

An underfill UF may be formed in a second molding layer ML2 from an upper surface of the bridge die BD to a lower surface of a first molding layer ML1. The underfill UF may surround the plurality of second metal pillars 130 and the plurality of connection bumps 140, which are disposed on the bridge die BD. The underfill UF may include, for example, epoxy resin. The underfill UF may be formed to have a width in the first horizontal direction X that gradually increases toward the first and second semiconductor chips 101 and 102 from the upper surface of the bridge die BD in the vertical direction Z. In some embodiments, the underfill UF may be omitted.

In general semiconductor packages, when a semiconductor chip is miniaturized or the number of signal terminals for input/output increases, it is difficult to accommodate all signal terminals within a main surface of the semiconductor chip. Therefore, a redistribution layer may be extended to the outside of the main surface of the semiconductor chip to expand a region where the signal terminals are arranged. In other words, a fan-out wafer level package (FO-WLP) or fan-out panel level package (FO-PLP) (hereinafter, collectively referred to as FO-WLP) structure is applied to general semiconductor packages.

The redistribution layer RDL may include a wiring layer, a vertical via vertically connected to the wiring layer, and an insulating layer surrounding the wiring layer and the vertical via. Structurally, an upper surface of the redistribution layer RDL and a lower surface of the bridge die BD may be in direct contact with each other.

The first molding layer ML1 may be formed to surround the first and second semiconductor chips 101 and 102 and the plurality of first metal pillars 110, and the second molding layer ML2 may be formed to surround the bridge die BD and the plurality of metal posts 120.

In some embodiments, each of the first and second molding layers ML1 and ML2 may include epoxy resin or polyimide resin. The first and second molding layers ML1 and ML2 may include, for example, an epoxy molding compound (EMC). In addition, the first and second molding layers ML1 and ML2 may include an identical material to each other or may include different materials from each other.

The first and second molding layers ML1 and ML2 may be formed to surround the first and second semiconductor chips 101 and 102 and the bridge die BD. In addition, the horizontal width of each of the first and second molding layers ML1 and ML2 may be substantially the same as the horizontal width of the semiconductor package 10. In addition, side surfaces of each of the first and second molding layers ML1 and ML2 and side surfaces of the redistribution layer RDL may be substantially coplanar with each other. In some embodiments, the first molding layer ML1 may be formed to expose upper surfaces of the first and second semiconductor chips 101 and 102 to the outside.

An external connection terminal CT may be formed on a lower surface of the redistribution layer RDL. The external connection terminal CT may include, for example, a solder ball, a conductive bump, a conductive paste, a ball grid array (BGA), a lead grid array (LGA), a pin grid array (PGA), or a combination thereof.

In the semiconductor package 10 according to an embodiment, a first width W1 of each of the plurality of first metal pillars 110 and a second width W2 of each of the plurality of metal posts 120 may be substantially equal to each other. In addition, a pitch P1, which is a distance between the centers of the plurality of first metal pillars 110 that are adjacent to each other, may be about 20 micrometers to about 100 micrometers. In this regard, a separation distance D1 between the first and second semiconductor chips 101 and 102 may be about 10 micrometers to about 1,000 micrometers. In addition, the plurality of first metal pillars 110 and the plurality of metal posts 120 may each include copper (Cu) and thus may be in contact with each other via copper-to-copper (Cu-to-Cu) direct bonding. The characteristics of the semiconductor package 10 are described in detail via a manufacturing method described below.

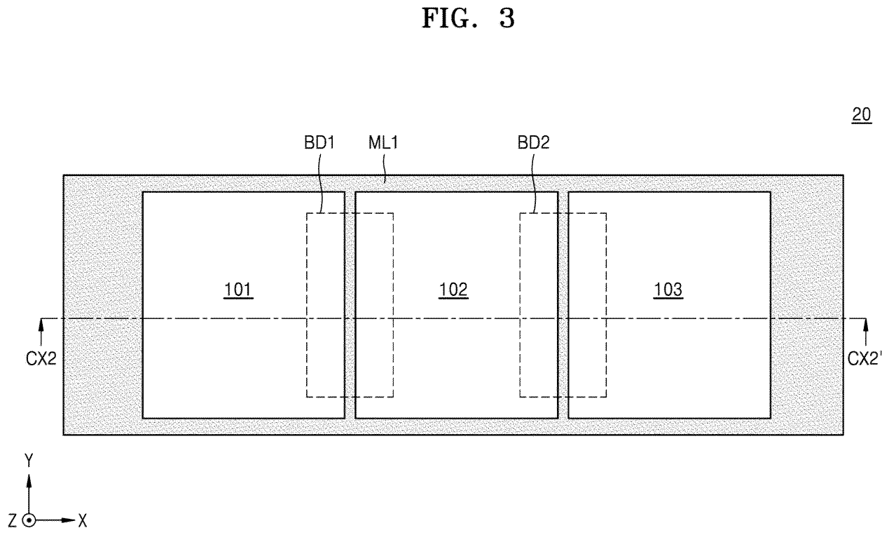

FIGS. 3 to 6 are views illustrating various embodiments.

Most of components of semiconductor packages 20, 30, and 40 described below and materials included in the components are substantially the same as or similar to those described with reference to FIGS. 1 and 2. Therefore, for convenience of explanation, differences from the semiconductor package 10 are mainly described.

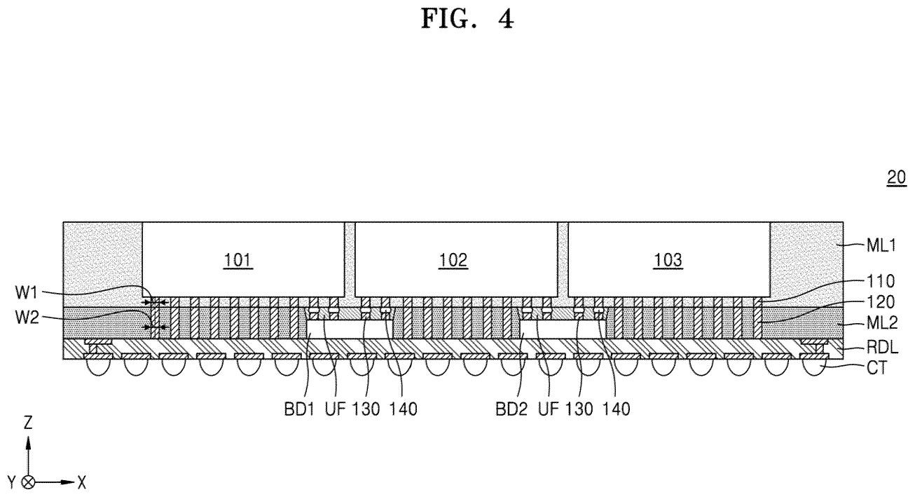

Referring to FIGS. 3 and 4, the semiconductor package 20 is shown that includes first to third semiconductor chips 101, 102, and 103 arranged parallel to each other in the first horizontal direction X and first and second bridge dies BD1 and BD2 arranged to overlap the first to third semiconductor chips 101, 102, and 103 in the vertical direction Z. In detail, FIG. 3 is a plan view of main components of the semiconductor package 20, and FIG. 4 is a cross-sectional view of the semiconductor package 20 taken along line CX2-CX2′ of FIG. 3.

In the semiconductor package 20 of the present embodiment, each of the first to third semiconductor chips 101, 102, and 103 is a memory chip, and for example, may include a volatile memory chip and/or a non-volatile memory chip. In some embodiments, the first to third semiconductor chips 101, 102, and 103 may be configured as a set of memory chips capable of merging data with each other.

The first and second bridge dies BD1 and BD2 may include a base substrate and the plurality of second metal pillars 130 formed on an upper surface of the base substrate. The base substrate may be a silicon wafer including silicon (Si), for example, crystalline silicon, polycrystalline silicon, or amorphous silicon. The plurality of second metal pillars 130 may be electrically connected with the first to third semiconductor chips 101, 102, and 103 via the plurality of connection bumps 140 formed on upper surfaces of the plurality of second metal pillars 130.

The first bridge die BD1 may be disposed below a region between the first and second semiconductor chips 101 and 102 to overlap each of the first and second semiconductor chips 101 and 102 in the vertical direction Z. In other words, in a plan view, a portion of the first bridge die BD1 may be arranged to overlap the first semiconductor chip 101, and another portion of the first bridge die BD1 may be arranged to overlap the second semiconductor chip 102.

In addition, the second bridge die BD2 may be disposed below a region between the second and third semiconductor chips 102 and 103 to overlap each of the second and third semiconductor chips 102 and 103 in the vertical direction Z. In other words, in a plan view, a portion of the second bridge die BD2 may be arranged to overlap the second semiconductor chip 102, and another portion of the second bridge die BD2 may be arranged to overlap the third semiconductor chip 103.

The redistribution layer RDL may include a wiring layer, a vertical via vertically connected to the wiring layer, and an insulating layer surrounding the wiring layer and the vertical via. Structurally, an upper surface of the redistribution layer RDL and lower surfaces of the first and second bridge dies BD1 and BD2 may be in direct contact with each other.

The first molding layer ML1 may be formed to surround the first to third semiconductor chips 101, 102, and 103 and the plurality of first metal pillars 110, and the second molding layer ML2 may be formed to surround the first and second bridge dies BD1 and BD2 and the plurality of metal posts 120.

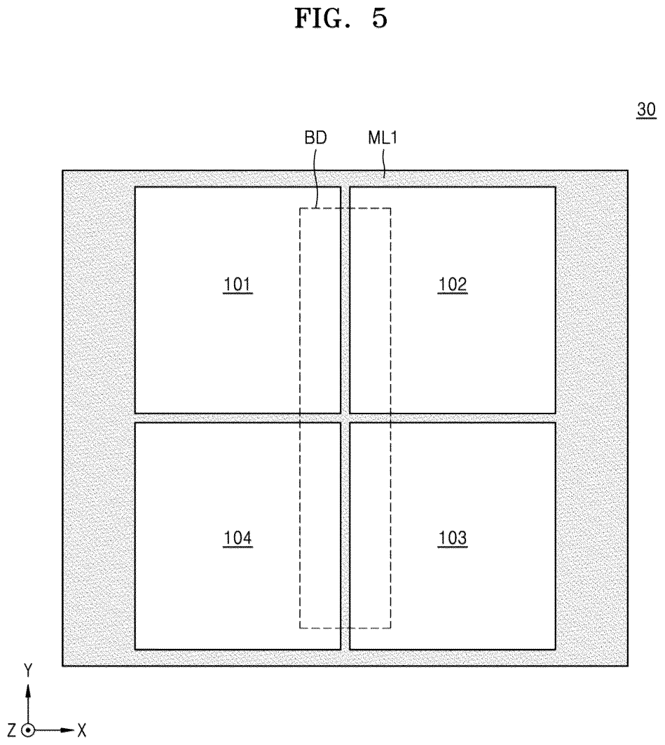

Referring to FIG. 5, the semiconductor package 30 is shown that includes first to fourth semiconductor chips 101, 102, 103, and 104 arranged apart from each other in the first horizontal direction X and a second horizontal direction Y and the bridge die BD arranged to overlap the first to fourth semiconductor chips 101, 102, 103, and 104 in the vertical direction Z. In detail, FIG. 5 is a plan view of some components of the semiconductor package 30, and a cross-sectional view thereof is omitted.

In the semiconductor package 30 of the present embodiment, each of the first to fourth semiconductor chips 101, 102, 103, and 104 is a memory chip, and for example, may include a volatile memory chip and/or a non-volatile memory chip. In some embodiments, the first to fourth semiconductor chips 101, 102, 103, and 104 may be configured as a set of memory chips capable of merging data with each other.

In a plan view, the first to fourth semiconductor chips 101, 102, 103, and 104 may be arranged in a quadrangular shape. However, in an embodiment, the number and arrangement shape of the semiconductor chips are not limited thereto.

The bridge die BD may be arranged at the center of the quadrangular shape formed by the first to fourth semiconductor chips 101, 102, 103, and 104. In addition, the bridge die BD may be disposed below a region between the first to fourth semiconductor chips 101, 102, 103, and 104 to overlap each of the first to fourth semiconductor chips 101, 102, 103, and 104 in the vertical direction Z. In other words, in a plan view, an upper left portion of the bridge die BD may be arranged to overlap the first semiconductor chip 101, an upper right portion of the bridge die BD may be arranged to overlap the second semiconductor chip 102, a lower right portion of the bridge die BD may be arranged to overlap the third semiconductor chip 103, and a lower left portion of the bridge die BD may be arranged to overlap the fourth semiconductor chip 104.

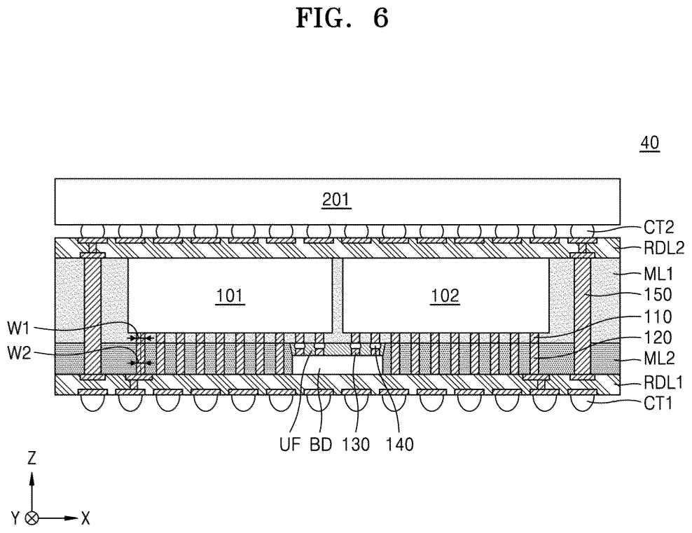

Referring to FIG. 6, the semiconductor package 40 is shown that includes the first and second semiconductor chips 101 and 102 arranged apart from each other in the first horizontal direction X, an upper semiconductor chip 201 disposed above the first and second semiconductor chips 101 and 102 to overlap the first and second semiconductor chips 101 and 102 in the vertical direction Z, and the bridge die BD disposed under the first and second semiconductor chips 101 and 102 to overlap the first and second semiconductor chips 101 and 102 in the vertical direction Z. In detail, FIG. 6 is a cross-sectional view of main components of the semiconductor package 40, and a plan view thereof is omitted.

In the semiconductor package 40 of the present embodiment, a first redistribution layer RDL1 corresponds to the redistribution layer RDL (see FIG. 2), and an external connection terminal CT1 corresponds to the external connection terminal CT (see FIG. 2).

The semiconductor package 40 of the present embodiment includes a plurality of connection posts 150 arranged around the first and second semiconductor chips 101 and 102 and electrically connected with the first redistribution layer RDL1 through the first and second molding layers ML1 and ML2. In addition, the semiconductor package 40 includes a second redistribution layer RDL2 formed on the first molding layer ML1, the plurality of connection posts 150, and the first and second semiconductor chips 101 and 102. In addition, the semiconductor package 40 includes the upper semiconductor chip 201 disposed above the second redistribution layer RDL2 and electrically connected to the second redistribution layer RDL2 via an internal connection terminal CT2.

In some embodiments, the upper semiconductor chip 201 may include a logic device. For example, the upper semiconductor chip 201 may be a central processing unit chip, a graphics processing unit chip, or an application processor chip. In other words, the upper semiconductor chip 201 and the first and second semiconductor chips 101 and 102 may perform different roles from each other.

The upper semiconductor chip 201 may include a semiconductor substrate having upper and lower surfaces facing each other, and the internal connection terminal CT2 formed on a lower surface of the semiconductor substrate. The internal connection terminal CT2 may be connected to the second redistribution layer RDL2.

The second redistribution layer RDL2 may include a wiring layer, a vertical via vertically connected to the wiring layer, and an insulating layer surrounding the wiring layer and the vertical via. Structurally, a lower surface of the second redistribution layer RDL2 and an upper surface of each of the first and second semiconductor chips 101 and 102 may be in direct contact with each other.

The plurality of connection posts 150 may electrically connect the first redistribution layer RDL1 to the second redistribution layer RDL2 through the first and second molding layers ML1 and ML2. The first and second molding layers ML1 and ML2 may surround the plurality of connection posts 150. The plurality of connection posts 150 may be formed around the first and second semiconductor chips 101 and 102.

The upper semiconductor chip 201 may be electrically connected with the first redistribution layer RDL1 via the internal connection terminal CT2, the second redistribution layer RDL2, and the plurality of connection posts 150.

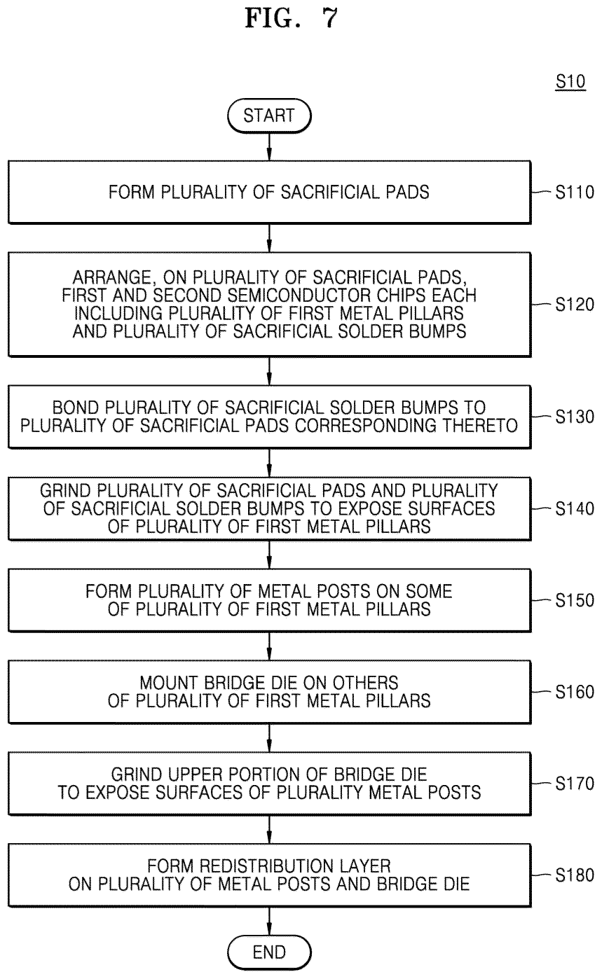

FIG. 7 is a flowchart illustrating a method of manufacturing a semiconductor package, according to an embodiment.

Referring to FIG. 7, a method S10 of manufacturing a semiconductor package may include a process order of first to eighth operations S110 to S1800.

When a certain embodiment is implemented differently, a specific process order may be performed differently from the described order. For example, two consecutively described processes may be performed substantially at the same time or performed in an order opposite to the described order.

The method S10 of manufacturing a semiconductor package may include: a first operation S110 of forming a plurality of sacrificial pads; a second operation S120 of arranging first and second semiconductor chips, each including a plurality of first metal pillars and a plurality of sacrificial solder bumps, on the plurality of sacrificial pads; a third operation S130 of bonding the plurality of sacrificial solder bumps to the plurality of sacrificial pads corresponding thereto; a fourth operation S140 of grinding the plurality of sacrificial pads and the plurality of sacrificial solder bumps to expose surfaces of the plurality of first metal pillars; a fifth operation S150 of forming a plurality of metal posts on some of the plurality of first metal pillars; a sixth operation S160 of mounting a bridge die on the others of the plurality of first metal pillars (that is, first metal pillars different and distinct from those first metal pillars mounting to the first and second semiconductor chips); a seventh operation S170 of grinding an upper portion of the bridge die to expose surfaces of the plurality of metal posts; and an eighth operation S180 of forming a redistribution layer on the plurality of metal posts and the bridge die.

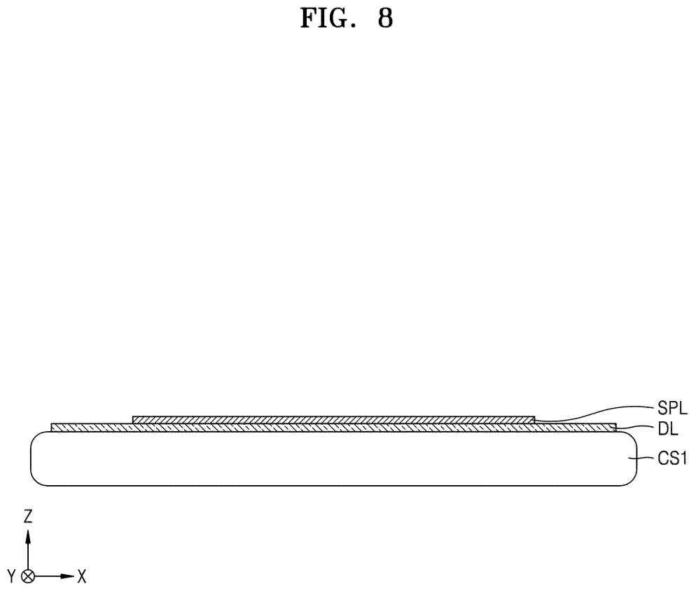

Technical features of the first to eighth operations S110 to S180 are described in detail with reference to FIGS. 8 to 21.

FIGS. 8 to 21 are cross-sectional views illustrating, in a process order, a method of manufacturing a semiconductor package, according to an embodiment.

Referring to FIG. 8, an adhesive insulating layer DL may be attached onto a first carrier substrate CS1, and a sacrificial pad layer SPL may be formed on the adhesive insulating layer DL.

The first carrier substrate CS1 may include, for example, glass, silicon, or aluminum oxide. The adhesive insulating layer DL may include any material capable of fixing the sacrificial pad layer SPL. The adhesive insulating layer DL may be, for example, an adhesive tape of which adhesion is weakened by heat treatment or by laser irradiation. The sacrificial pad layer SPL may be a conductive layer including copper (Cu).

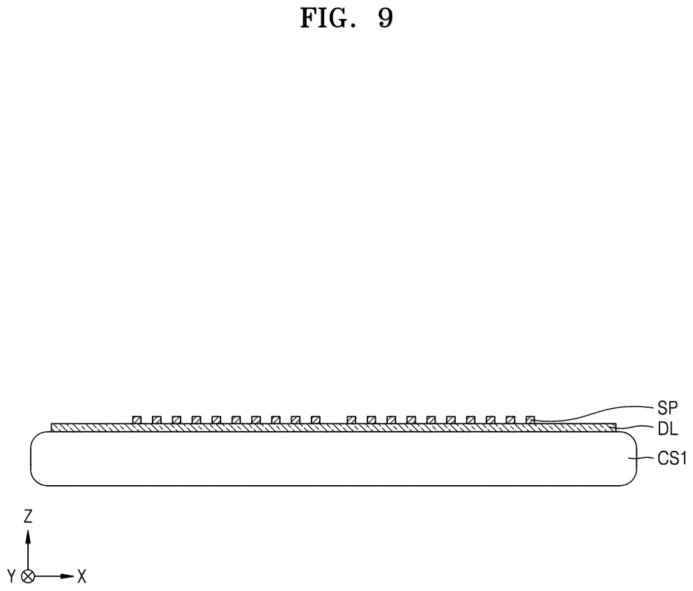

Referring to FIG. 9, a plurality of sacrificial pads SP may be formed on the sacrificial pad layer SPL (see FIG. 8) via patterning by a photolithography process and an etching process.

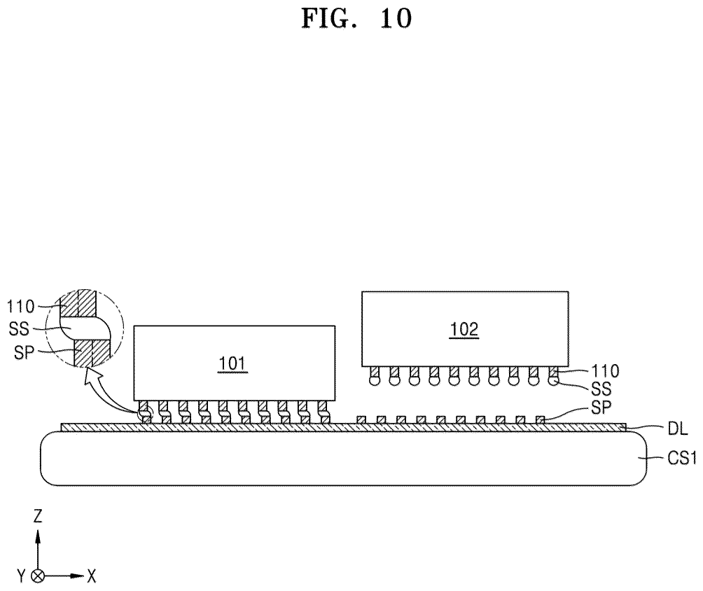

The plurality of sacrificial pads SP may be formed to have fine gaps between each other. For example, the plurality of sacrificial pads SP may be formed to have a pitch of about 20 micrometers to about 100 micrometers, but the pitch is not limited thereto. The plurality of sacrificial pads SP may be formed in a region where the first and second semiconductor chips 101 and 102 (see FIG. 10) are mounted.

Referring to FIG. 10, the first and second semiconductor chips 101 and 102, each including the plurality of first metal pillars 110 and a plurality of sacrificial solder bumps SS disposed below the plurality of first metal pillars 110, may be arranged parallel to each other on the plurality of sacrificial pads SP.

First, the plurality of sacrificial solder bumps SS and the plurality of sacrificial pads SP corresponding thereto may be in contact with each other between the first semiconductor chip 101 and the first carrier substrate CS1. In this case, as shown in the drawing, the central axes of the plurality of first metal pillars 110 and the central axes of the plurality of sacrificial pads SP may be arranged to be offset from each other with the plurality of sacrificial solder bumps SS therebetween. This may be due to errors occurring during an alignment process of fine patterns.

Next, the plurality of sacrificial solder bumps SS and the plurality of sacrificial pads SP corresponding thereto may be in contact with each other between the second semiconductor chip 102 and the first carrier substrate CS1. In this regard, the first semiconductor chip 101 and the second semiconductor chip 102 may be arranged to have a separation distance of about 10 micrometers to about 1,000 micrometers.

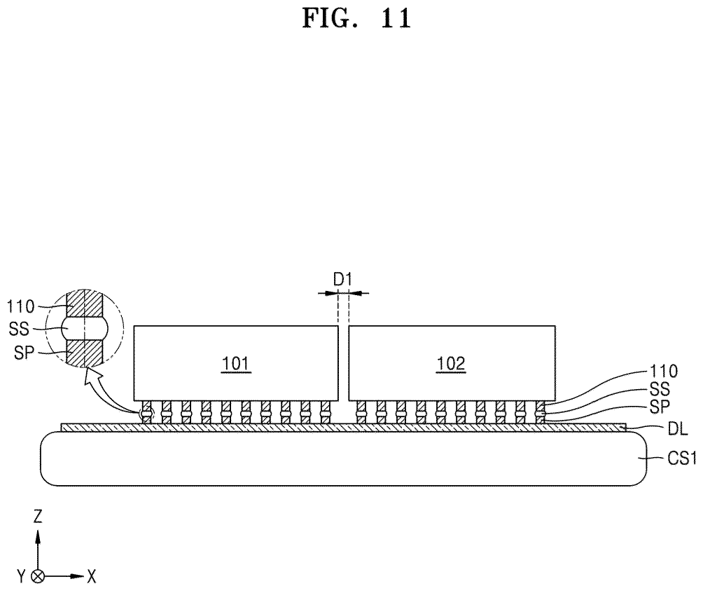

Referring to FIG. 11, a reflow process may be performed on the plurality of sacrificial solder bumps SS to self-align the plurality of first metal pillars 110 and the plurality of sacrificial pads SP with each other.

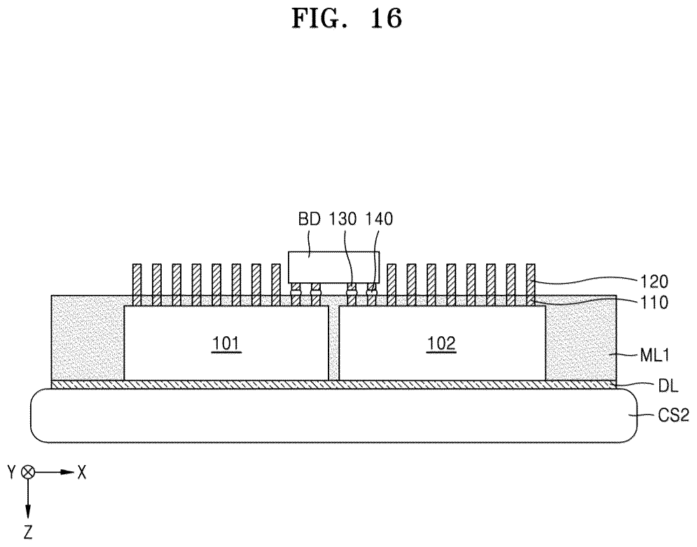

The plurality of sacrificial solder bumps SS may be melted by the reflow process. In this case, as shown in the drawing, due to the surface tension of the melted plurality of sacrificial solder bumps SS, the central axes of the plurality of first metal pillars 110 and the central axes of the plurality of sacrificial pads SP may be aligned to coincide with each other with the plurality of sacrificial solder bumps SS therebetween. In other words, without using an additional process, the plurality of first metal pillars 110 and the plurality of sacrificial pads SP may be aligned without errors. Using this self-alignment, the separation distance D1 between the first and second semiconductor chips 101 and 102 may be relatively small (for example, about 10 micrometers to about 1,000 micrometers). A physical property of a fluid is that surface tension acts to minimize a surface area of the fluid. A misalignment, see the zoom-in view of pillar 110 in FIG. 10, causes a balancing force on a horizontally-displaced pillar, thus the pillars 110 and pads SP tend to align. When the pillars 110 and pads SP are aligned, they are at a low energy position kinetically because the surface area of the melted bumps tends to be at or near a minimum. When the pillars 110 and pads SP are not aligned, they do not tend to stay unaligned, because the balancing force is in a direction to reach the low energy position; that low energy position corresponds to alignment. The same mechanism applies to alignment based on surface tension elsewhere in this application, for example for pillars 110 and pillars 130 discussed with respect to FIG. 16.

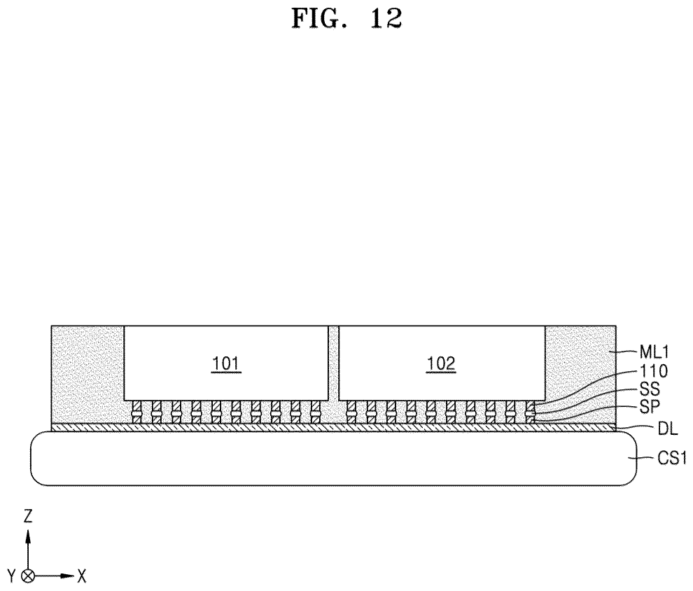

Referring to FIG. 12, the first molding layer ML1 may be formed to surround side surfaces and lower surfaces of the first and second semiconductor chips 101 and 102.

In detail, the first molding layer ML1 may be formed on the adhesive insulating layer DL to surround the first and second semiconductor chips 101 and 102, the plurality of first metal pillars 110, the plurality of sacrificial solder bumps SS, and the plurality of sacrificial pads SP. The first molding layer ML1 may serve to protect the first and second semiconductor chips 101 and 102 from external influences such as shock and contamination.

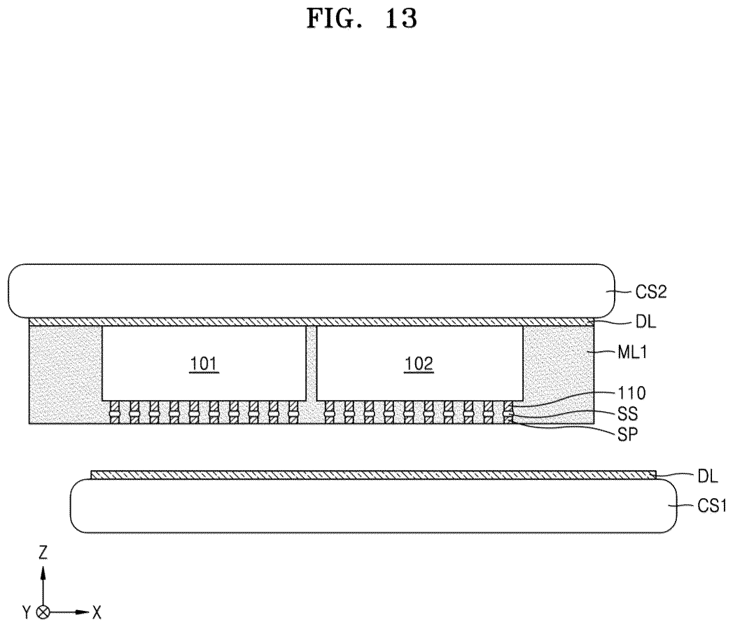

Referring to FIG. 13, a second carrier substrate CS2 may be attached onto the first and second semiconductor chips 101 and 102 to face the first carrier substrate CS1.

The second carrier substrate CS2 may be attached to remove the first carrier substrate CS1 and perform a subsequent process. The second carrier substrate CS2 may include, for example, glass, silicon, or aluminum oxide.

In some embodiments, a laser beam may be irradiated to the first carrier substrate CS1 to separate the first carrier substrate CS1. Due to the irradiation of the laser beam, a bonding force between the adhesive insulating layer DL and the first carrier substrate CS1 may be weakened. In some embodiments, heat may be applied to the adhesive insulating layer DL on the first carrier substrate CS1.

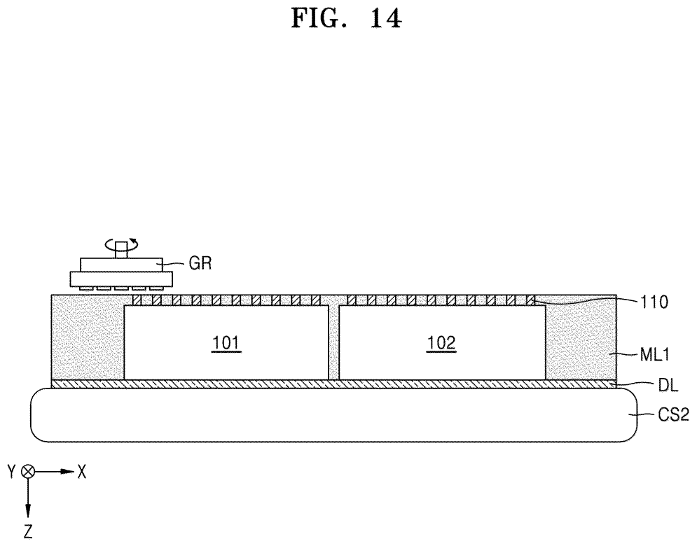

Referring to FIG. 14, the second carrier substrate CS2 may be turned over, and a portion of the first molding layer ML1, the plurality of sacrificial pads SP (see FIG. 13), and the plurality of sacrificial solder bumps SS (see FIG. 13) may be removed, to expose the plurality of first metal pillars 110.

A grinding and flattening process is performed using a grinder GR. The grinding and flattening process may be a chemical mechanical grinding process. The grinder GR may remove a portion of the first molding layer ML1, the plurality of sacrificial pads SP (see FIG. 13), and the plurality of sacrificial solder bumps (see FIG. 13), such that an upper surface of the first molding layer ML1 and upper surfaces of the plurality of first metal pillars 110 may be formed as one flat surface.

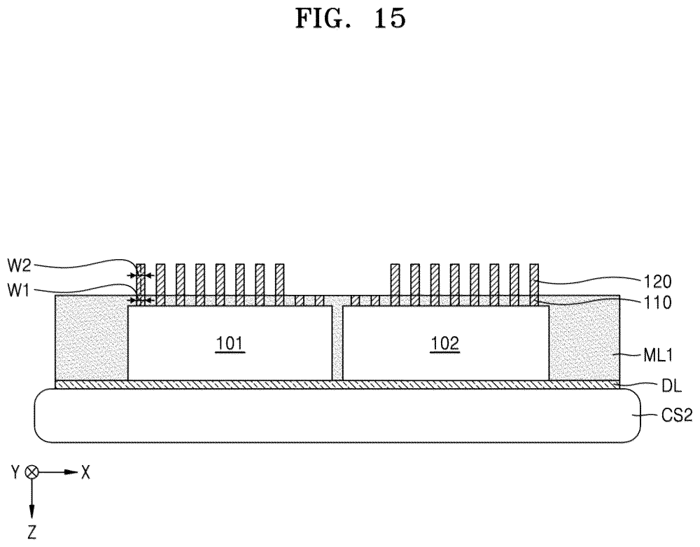

Referring to FIG. 15, the plurality of metal posts 120 may be formed on some of the exposed plurality of first metal pillars 110.

The plurality of metal posts 120 may be formed on some of the plurality of first metal pillars 110 via a photolithography process and a plating process. The others of the plurality of first metal pillars 110 are regions on which the bridge die BD (see FIG. 16) is to be mounted, and thus, the plurality of metal posts 120 may not be formed on the others of the plurality of first metal pillars 110.

In this regard, the first width W1 of each of the plurality of first metal pillars 110 and the second width W2 of each of the plurality of metal posts 120 may be substantially equal to each other. In addition, the plurality of first metal pillars 110 and the plurality of metal posts 120 may each include copper (Cu) and thus may be in contact with each other via copper-to-copper direct bonding.

Referring to FIG. 16, the bridge die BD including the plurality of second metal pillars 130 and the plurality of connection bumps 140 disposed below the plurality of second metal pillars 130 is disposed on the others of the exposed plurality of first metal pillars 110.

A reflow process may be performed on the plurality of connection bumps 140 to self-align the plurality of second metal pillars 130 and the plurality of first metal pillars 110 with each other. The plurality of connection bumps 140 may be melted by the reflow process. In this case, due to the surface tension of the melted plurality of connection bumps 140, the central axes of the plurality of second metal pillars 130 and the central axes of the plurality of first metal pillars 110 may be aligned to coincide with each other.

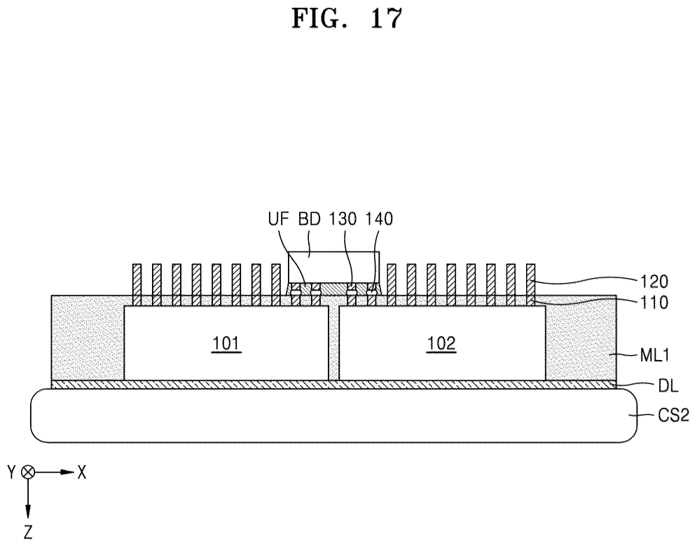

Referring to FIG. 17, the underfill UF may be injected and cured to reinforce the connection of the bridge die BD.

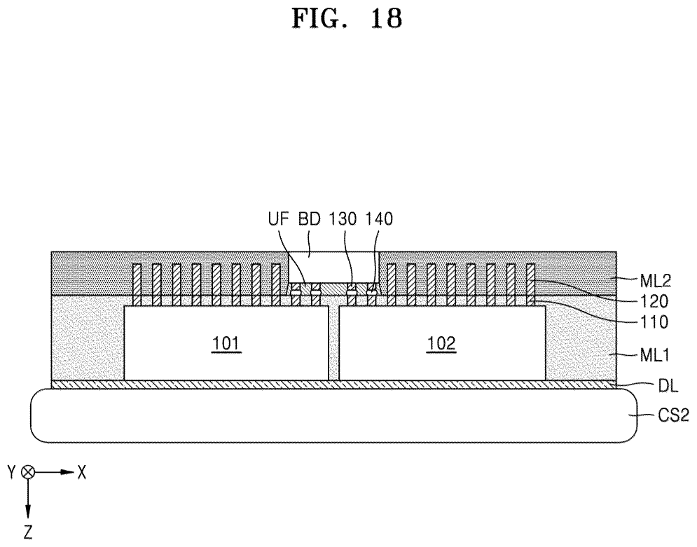

The plurality of second metal pillars 130, the plurality of connection bumps 140, and the bridge die BD may be further stably fixed by the underfill UF. In some embodiments, the second molding layer ML2 (see FIG. 18) may be directly filled under the bridge die BD, and in this case, the underfill UF may be omitted.

The underfill UF may be formed from a lower surface of the bridge die BD to an upper surface of the first molding layer ML1. The underfill UF may be formed to have a width in the first horizontal direction X that gradually increases toward the first and second semiconductor chips 101 and 102 from the lower surface of the bridge die BD in the vertical direction Z.

Referring to FIG. 18, the second molding layer ML2 may be formed to surround side surfaces of the bridge die BD.

In detail, the second molding layer ML2 may be formed on the first molding layer ML1 to surround the bridge die BD, the plurality of metal posts 120, and the underfill UF. The second molding layer ML2 may serve to protect the bridge die BD from external influences such as shock and contamination.

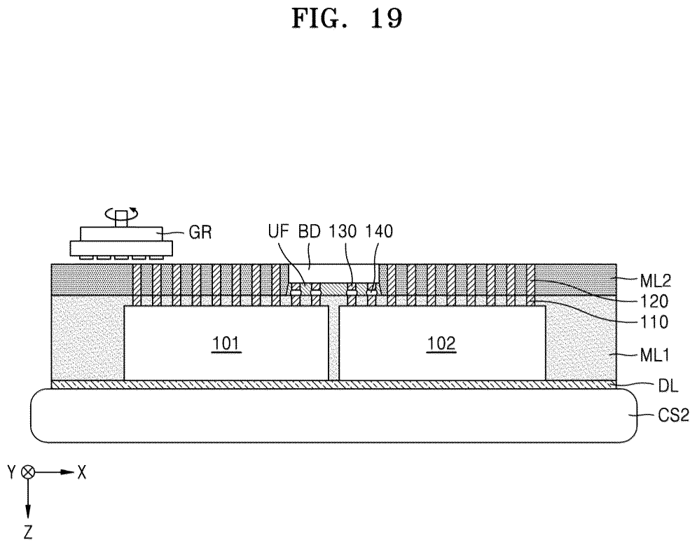

Referring to FIG. 19, a portion of the second molding layer ML2 and an upper portion of the bridge die BD may be removed to expose the plurality of metal posts 120.

A grinding and flattening process is performed using the grinder GR. The grinder GR may remove a portion of the second molding layer ML2 and an upper portion of the bridge die BD to form a flat surface through which the bridge die BD and the plurality of metal posts 120 are exposed. Accordingly, the total thickness of the bridge die BD may be reduced, and warpage of the bridge die BD may be reduced.

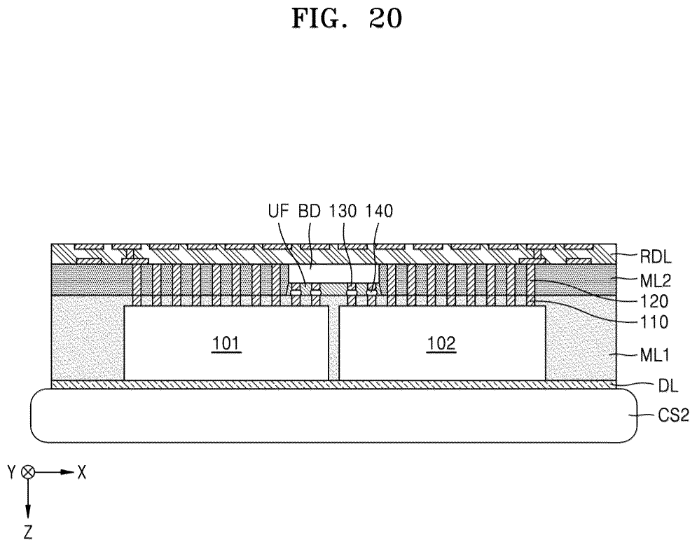

Referring to FIG. 20, the redistribution layer RDL may be formed on the second molding layer ML2, the plurality of metal posts 120, and the bridge die BD, each having a flat surface via a grinding and flattening process.

The redistribution layer RDL may include a wiring layer, a vertical via vertically connected to the wiring layer, and an insulating layer surrounding the wiring layer and the vertical via. A lower surface of the redistribution layer RDL and an upper surface of the bridge die BD may be in direct contact with each other, and the lower surface of the redistribution layer RDL and upper surfaces of the plurality of metal posts 120 may be in direct contact with each other.

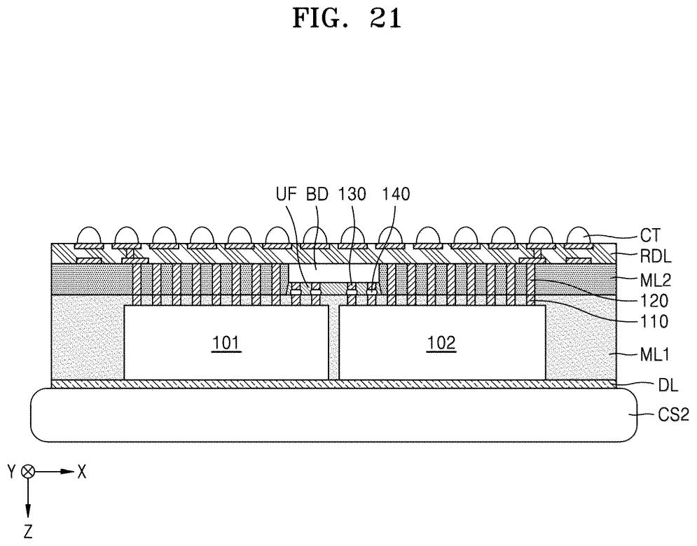

Referring to FIG. 21, the external connection terminal CT may be formed on an upper surface of the redistribution layer RDL.

The external connection terminal CT may include, for example, a solder ball, a conductive bump, a conductive paste, a BGA, an LGA, a PGA, or a combination thereof. The external connection terminal CT may be formed on a distribution pad connected with the wiring layer of the redistribution layer RDL.

Referring back to FIG. 2, the second carrier substrate CS2 may be turned over, and the second carrier substrate CS2 may be separated. In some embodiments, a laser beam may be irradiated to the adhesive insulating layer DL on the second carrier substrate CS2. In some embodiments, heat may be applied to the adhesive insulating layer DL on the second carrier substrate CS2.

As described above, according to a method of manufacturing a semiconductor package according to the embodiments, by self-aligning the first and second semiconductor chips 101 and 102 on pads having fine gaps due to the surface tension of solder bumps, a distance between the first and second semiconductor chips 101 and 102 may be minimized, thereby reducing the size of the semiconductor package 10.

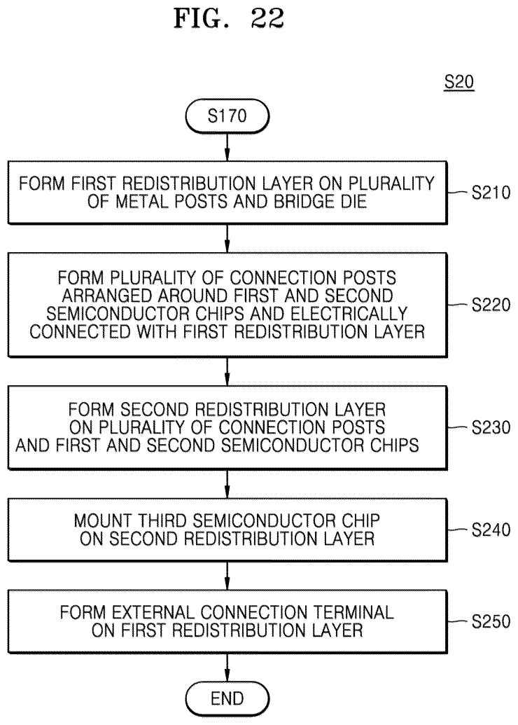

FIG. 22 is a flowchart illustrating a method of manufacturing a semiconductor package, according to another embodiment.

Referring to FIG. 22, a method S20 of manufacturing a semiconductor package may include a process order of first to fifth operations S210 to S250.

When a certain embodiment is implemented differently, a specific process order may be performed differently from the described order. For example, two consecutively described processes may be performed substantially at the same time or performed in an order opposite to the described order.

The method S20 may proceed in the same manner up to the seventh operation S170 of the method S10 (see FIG. 7) of manufacturing a semiconductor package as described above.

The method S20 of manufacturing a semiconductor package may include: a first operation S210 of forming a first redistribution layer on a plurality of metal posts and a bridge die; a second operation S220 of forming a plurality of connection posts arranged around first and second semiconductor chips and electrically connected with the first redistribution layer; a third operation S230 of forming a second redistribution layer on the plurality of connection posts and the first and second semiconductor chips; a fourth operation S240 of mounting a third semiconductor chip on the second redistribution layer; and a fifth operation S250 of forming an external connection terminal on the first redistribution layer.

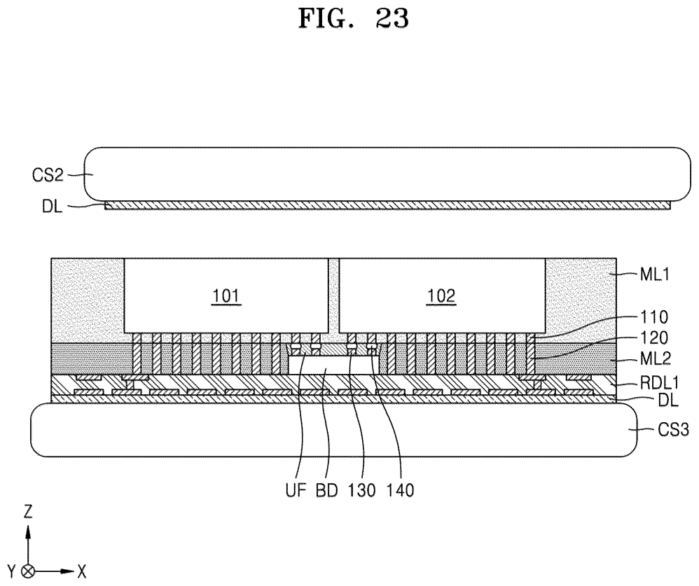

Technical features of the first to fifth operations S210 to S250 are described in detail with reference to FIGS. 23 to 28.

FIGS. 23 to 28 are cross-sectional views illustrating, in a process order, a method of manufacturing a semiconductor package, according to another embodiment.

Referring to FIG. 23, the manufacturing operations of FIGS. 8 to 20 described above may be performed in the same manner, the second carrier substrate CS2 may be turned over, and a third carrier substrate CS3 may be attached onto the first redistribution layer RDL1 to face the second carrier substrate CS2.

In the present embodiment, the first redistribution layer RDL1 corresponds to the redistribution layer RDL (see FIG. 20). The third carrier substrate CS3 may be attached to remove the second carrier substrate CS2 and perform a subsequent process. The third carrier substrate CS3 may include, for example, glass, silicon, or aluminum oxide.

The second carrier substrate CS2 may be separated. In some embodiments, a laser beam may be irradiated to the adhesive insulating layer DL on the second carrier substrate CS2. In some embodiments, heat may be applied to the adhesive insulating layer DL on the second carrier substrate CS2.

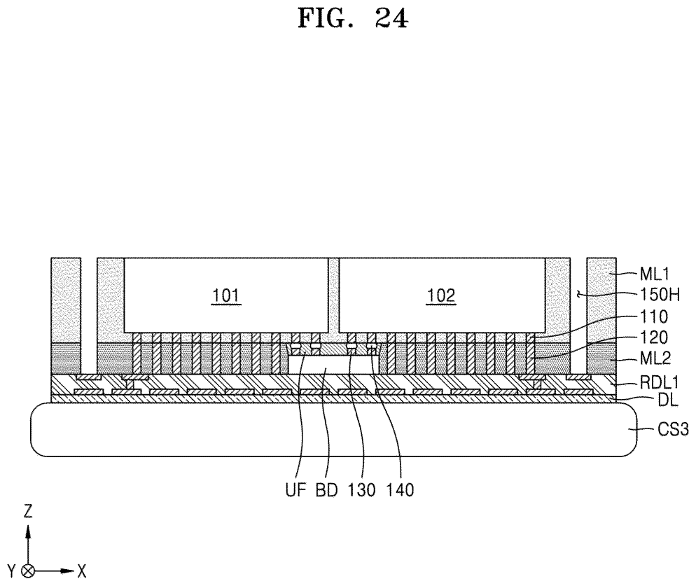

Referring to FIG. 24, a plurality of openings 150H passing through the first and second molding layers ML1 and ML2 may be formed around the first and second semiconductor chips 101 and 102.

The plurality of openings 150H may be formed via patterning by a photolithography process and an etching process. A portion of an upper surface of the first redistribution layer RDL1 may be exposed by the plurality of openings 150H.

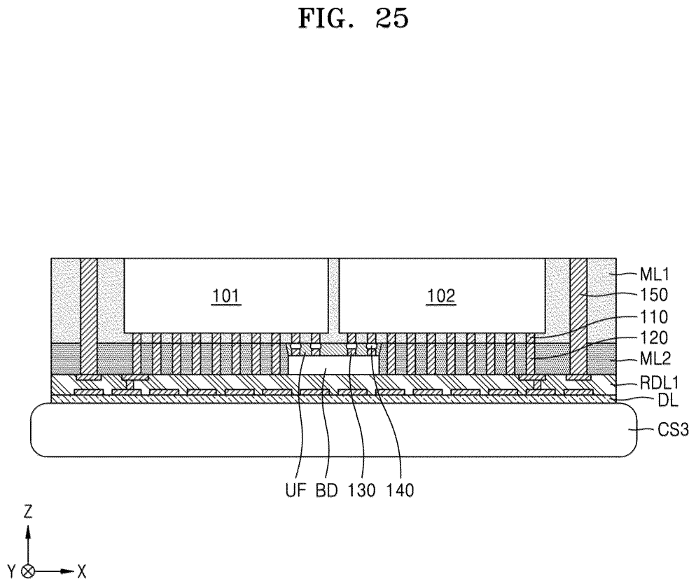

Referring to FIG. 25, the plurality of connection posts 150 may be formed by filling the plurality of openings 150H (see FIG. 24) with a conductive material.

The plurality of connection posts 150 may be formed via plating. In detail, the exposed upper surface of the first redistribution layer RDL1 may function as a seed layer for forming the plurality of connection posts 150. In some embodiments, the conductive material may include copper (Cu) or a copper (Cu) alloy, but is not limited thereto.

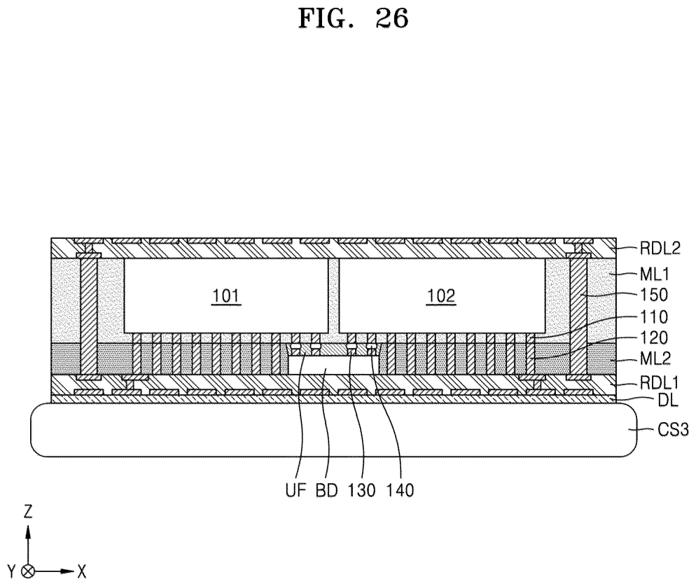

Referring to FIG. 26, the second redistribution layer RDL2 may be formed on the first molding layer ML1, the plurality of connection posts 150, and the first and second semiconductor chips 101 and 102, each having a flat surface.

The second redistribution layer RDL2 may include a wiring layer, a vertical via vertically connected to the wiring layer, and an insulating layer surrounding the wiring layer and the vertical via. A lower surface of the second redistribution layer RDL2 and upper surfaces of the first and second semiconductor chips 101 and 102 may be in direct contact with each other, and the lower surface of the second redistribution layer RDL2 and upper surfaces of the plurality of connection posts 150 may be in direct contact with each other.

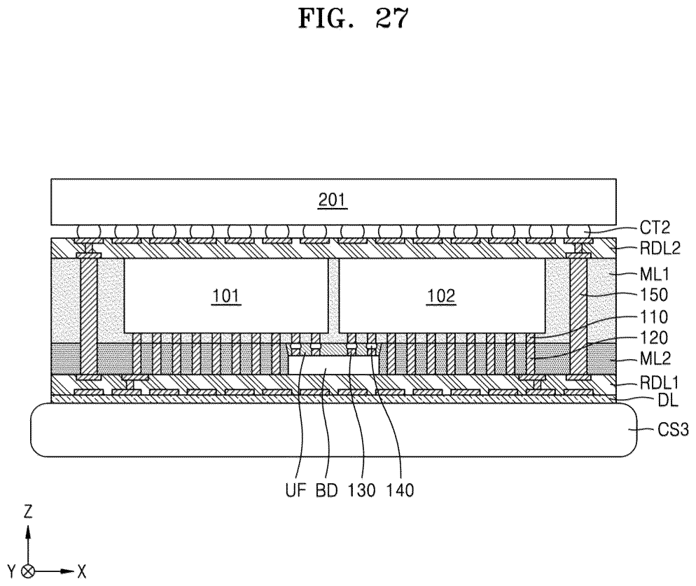

Referring to FIG. 27, the upper semiconductor chip 201 may be mounted to be electrically connected with the second redistribution layer RDL2.

The upper semiconductor chip 201 may be attached onto the second redistribution layer RDL2 such that the internal connection terminal CT2 faces the second redistribution layer RDL2. In some embodiments, the upper semiconductor chip 201 may be electrically connected with the first redistribution layer RDL1 via the internal connection terminal CT2, the second redistribution layer RDL2, and the plurality of connection posts 150.

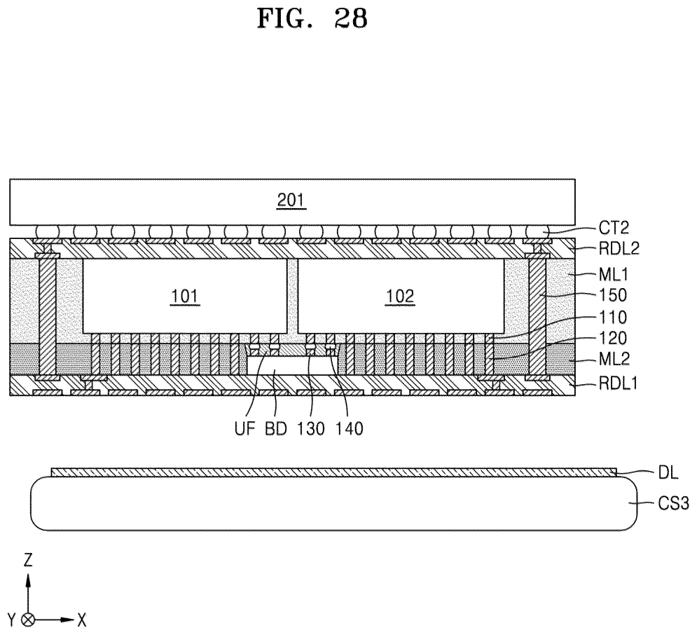

Referring to FIG. 28, the third carrier substrate CS3 may be separated from the second redistribution layer RDL2.

In some embodiments, a laser beam may be irradiated to the third carrier substrate CS3. Due to the irradiation of the laser beam, a bonding force between the adhesive insulating layer DL and the third carrier substrate CS3 may be weakened. In some embodiments, heat may be applied to the adhesive insulating layer DL on the third carrier substrate CS3.

Referring back to FIG. 6, the external connection terminal CT1 may be formed on a lower surface of the first redistribution layer RDL1.

The external connection terminal CT1 may include, for example, a solder ball, a conductive bump, a conductive paste, a BGA, an LGA, a PGA, or a combination thereof. The external connection terminal CT1 may be formed on a distribution pad connected with the wiring layer of the first redistribution layer RDL1.

As described above, according to the method of manufacturing a semiconductor package, by self-aligning the first and second semiconductor chips 101 and 102 on pads having fine gaps due to the surface tension of solder bumps, a distance between the first and second semiconductor chips 101 and 102 may be minimized, thereby reducing the size of the semiconductor package 40.

Various changes in form and details may be made therein without departing from the spirit and scope of the following claims.

What is claimed is:

1. A method of manufacturing a semiconductor package, the method comprising:
forming, on a first carrier substrate, a plurality of sacrificial pads each having a first width;
arranging, on the plurality of sacrificial pads, first semiconductor chips and second semiconductor chips disposed to be parallel to the first semiconductor chips, each of the first and the second semiconductor chips comprising a plurality of first metal pillars each having the first width and a plurality of sacrificial solder bumps disposed below the plurality of first metal pillars;
bonding the plurality of sacrificial solder bumps to the plurality of sacrificial pads corresponding thereto between the first and the second semiconductor chips and the first carrier substrate;
forming a first molding layer to at least partially surround the plurality of sacrificial pads, the plurality of sacrificial solder bumps, the plurality of first metal pillars, and the first and second semiconductor chips;
attaching a second carrier substrate onto upper surfaces of the first semiconductor chips and upper surfaces of the second semiconductor chips and removing the first carrier substrate;
first grinding and removing all of the plurality of sacrificial pads and the plurality of sacrificial solder bumps to at least partially expose the plurality of first metal pillars;
forming a plurality of metal posts on some of the plurality of first metal pillars;
bonding a plurality of connection bumps to others of the plurality of first metal pillars corresponding thereto such that a bridge die comprising a plurality of second metal pillars and the plurality of connection bumps disposed below the plurality of second metal pillars overlaps a portion of each of the first and second semiconductor chips in a vertical direction;
forming an underfill between the bridge die and the first molding layer to at least partially surround the plurality of second metal pillars and the plurality of connection bumps;
forming a second molding layer to at least partially surround the plurality of metal posts, the underfill, and the bridge die;
second grinding and removing a first upper portion of the bridge die and a second upper portion of the second molding layer to at least partially expose the plurality of metal posts;
forming a redistribution layer on the second molding layer, the plurality of metal posts, and the bridge die;
forming an external connection terminal on the redistribution layer; and
removing the second carrier substrate.

2. The method of claim 1, wherein, in the bonding of the plurality of sacrificial solder bumps to the plurality of sacrificial pads corresponding thereto, the bonding comprises performing a reflow process on the plurality of sacrificial solder bumps to self-align the plurality of first metal pillars and the plurality of sacrificial pads with each other due to surface tension of the plurality of sacrificial solder bumps.

3. The method of claim 1, wherein the plurality of first metal pillars and the plurality of metal posts each comprise copper (Cu) and are in contact with each other via copper-to-copper (Cu-to-Cu) direct bonding, and
the plurality of connection bumps are arranged between the plurality of first metal pillars and the plurality of second metal pillars.

4. The method of claim 3, wherein a first interface between the first molding layer and the second molding layer is coplanar with a second interface between the plurality of first metal pillars and the plurality of metal posts.

5. The method of claim 4, wherein the first molding layer and the second molding layer comprise different materials from each other.

6. The method of claim 1, wherein the underfill has a width in a horizontal direction that gradually increases toward the first semiconductor chips and the second semiconductor chips.

7. The method of claim 1, wherein, in the removing of the first carrier substrate, lower surfaces of the plurality of sacrificial pads and a lower surface of the first molding layer are exposed.

8. The method of claim 1, wherein, in the secondarily grinding and removing, the first upper portion of the bridge die is removed, and warpage of the bridge die is reduced.

9. The method of claim 1, wherein, in the forming of the plurality of sacrificial pads, the forming comprises forming the plurality of sacrificial pads via patterning by a first photolithography process and an etching process, and
in the forming of the plurality of metal posts, the forming comprises forming the plurality of metal posts via patterning by a second photolithography process and a plating process.

10. The method of claim 1, wherein a pitch of the plurality of first metal pillars is about 20 micrometers to about 100 micrometers, and
a separation distance between the first and second semiconductor chips is about 10 micrometers to about 1,000 micrometers.

11. A method of manufacturing a semiconductor package, the method comprising:
forming, on a first carrier substrate, a plurality of sacrificial pads;
arranging, on the plurality of sacrificial pads, a plurality of semiconductor chips disposed to be parallel to each other, each of the plurality of semiconductor chips comprising a plurality of first metal pillars and a plurality of sacrificial solder bumps disposed below the plurality of first metal pillars;
bonding the plurality of sacrificial solder bumps to the plurality of sacrificial pads corresponding thereto between the plurality of semiconductor chips and the first carrier substrate, wherein the plurality of first metal pillars and the plurality of sacrificial pads are self-aligned with each other due to surface tension of the plurality of sacrificial solder bumps;
forming a first molding layer to at least partially surround the plurality of sacrificial pads, the plurality of sacrificial solder bumps, the plurality of first metal pillars, and the plurality of semiconductor chips;
attaching a second carrier substrate onto upper surfaces of the plurality of semiconductor chips and removing the first carrier substrate;
first grinding and removing all of the plurality of sacrificial pads and the plurality of sacrificial solder bumps to at least partially expose the plurality of first metal pillars;
forming a plurality of metal posts on some of the plurality of first metal pillars;
bonding a plurality of connection bumps to others of the plurality of first metal pillars corresponding thereto such that at least one bridge die comprising a plurality of second metal pillars and the plurality of connection bumps disposed below the plurality of second metal pillars overlaps portions of at least two of the plurality of semiconductor chips in a vertical direction;
forming at least one underfill between each of the at least one bridge die and the first molding layer to at least partially surround the plurality of second metal pillars and the plurality of connection bumps;
forming a second molding layer, wherein the second molding layer is configured to at least partially surround the plurality of metal posts, the at least one underfill, and the at least one bridge die;
second grinding and removing an upper portion of the at least one bridge die and an upper portion of the second molding layer to at least partially expose the plurality of metal posts; and
forming a redistribution layer on the second molding layer, the plurality of metal posts, and the at least one bridge die.

12. The method of claim 11, wherein the plurality of semiconductor chips comprises a first semiconductor chip, a second semiconductor chip and a third semiconductor chip arranged parallel to each other in a horizontal direction, and
the at least one bridge die comprises a first bridge die that overlaps portions of the first semiconductor chip and the second semiconductor chip in the vertical direction, and a second bridge die that overlaps portions of the second semiconductor chip and the third semiconductor chip in the vertical direction.

13. The method of claim 12, wherein the at least one underfill comprises a first underfill corresponding to the first bridge die and a second underfill corresponding to the second bridge die, and
each of the first underfill and the second underfill has a width in the horizontal direction that gradually increases toward the first semiconductor chip to third the semiconductor chip.

14. The method of claim 11, wherein the plurality of semiconductor chips comprises a first semiconductor chip, a second semiconductor chip, a third semiconductor chip and a fourth semiconductor chip arranged in a quadrangular shape, and
the at least one bridge die is arranged at a center of the quadrangular shape and overlaps a portion of each of the first semiconductor chip to the fourth semiconductor chip.

15. The method of claim 11, wherein, in the forming of the plurality of metal posts, the forming comprises not forming the plurality of metal posts in a region where the at least one bridge die is to be arranged.

16. A method of manufacturing a semiconductor package, the method comprising:
forming, on a first carrier substrate, a plurality of sacrificial pads each having a first width;
arranging, on the plurality of sacrificial pads, first semiconductor chips and second semiconductor chips disposed to be parallel to the first semiconductor chips, each of the first and the second semiconductor chips comprising a plurality of first metal pillars each having the first width and a plurality of sacrificial solder bumps disposed below the plurality of first metal pillars;
bonding the plurality of sacrificial solder bumps to the plurality of sacrificial pads corresponding thereto between the first and the second semiconductor chips and the first carrier substrate;
forming a first molding layer to at least partially surround the plurality of sacrificial pads, the plurality of sacrificial solder bumps, the plurality of first metal pillars, and the first and second semiconductor chips;
attaching a second carrier substrate onto upper surfaces of the first semiconductor chips and upper surfaces of the second semiconductor chips and removing the first carrier substrate;
first grinding and removing all of the plurality of sacrificial pads and the plurality of sacrificial solder bumps to at least partially expose the plurality of first metal pillars;
forming a plurality of metal posts on some of the plurality of first metal pillars;
bonding a plurality of connection bumps to others of the plurality of first metal pillars corresponding thereto such that a bridge die comprising a plurality of second metal pillars and the plurality of connection bumps disposed below the plurality of second metal pillars overlaps a portion of each of the first and the second semiconductor chips in a vertical direction;
forming an underfill between the bridge die and the first molding layer to at least partially surround the plurality of second metal pillars and the plurality of connection bumps;
forming a second molding layer to at least partially surround the plurality of metal posts, the underfill, and the bridge die;
second grinding and removing an upper portion of the bridge die and an upper portion of the second molding layer to at least partially expose the plurality of metal posts;
forming a first redistribution layer on the second molding layer, the plurality of metal posts, and the bridge die;
attaching a third carrier substrate onto the first redistribution layer and removing the second carrier substrate;
forming a plurality of connection posts arranged around the first and the second semiconductor chips and electrically connected with the first redistribution layer through the first molding layer and the second molding layer;
forming a second redistribution layer on the first molding layer, the plurality of connection posts, and the first and the second semiconductor chips;
arranging a third semiconductor chip on the second redistribution layer; and
removing the third carrier substrate.

17. The method of claim 16, wherein the third semiconductor chip comprises a single logic chip, and
the first and second semiconductor chips are configured as a set of memory chips capable of merging data with each other.

18. The method of claim 17, wherein the bridge die is configured to enable a transmission of data signals between the first and the second semiconductor chips via the bridge die, and
the third semiconductor chip is electrically connected with the first redistribution layer via the second redistribution layer and the plurality of connection posts.

19. The method of claim 16, wherein, in the bonding of the plurality of sacrificial solder bumps to the plurality of sacrificial pads corresponding thereto, the bonding comprises performing a reflow process on the plurality of sacrificial solder bumps to self-align the plurality of first metal pillars and the plurality of sacrificial pads with each other due to surface tension of the plurality of sacrificial solder bumps.

20. The method of claim 16, wherein the plurality of first metal pillars and the plurality of metal posts each comprise copper (Cu) and are in contact with each other via copper-to-copper (Cu-to-Cu) direct bonding, and
the plurality of connection bumps are arranged between the plurality of first metal pillars and the plurality of second metal pillars.
